(19) United States
(12) Patent Application Publication
(10) Pub. No.: US 2024/0096718 A1
(43) Pub. Date: Mar. 21, 2024

(54) TESTKEY STRUCTURE AND METHOD FOR FORMING THE SAME

(71) Applicant: Winbond Electronics Corp., Taichung City (TW)

(72) Inventor: Chung-Hsuan WANG, Taichung City (TW)

(21) Appl. No.: 17/945,606

(22) Filed: Sep. 15, 2022

(51) Int. Cl. H01L 21/66; G01R 31/28

(52) U.S. Cl. CPC H01L 22/34; G01R 31/2884; H01L 22/32

(57) ABSTRACT

A testkey structure includes a substrate, a control gate, a metal gate, a dielectric structure, a source line, and a drain line. The control gate is disposed over the substrate and includes a first region and a second region. The second region is adjacent to the first region. The first region has a first conductivity type, and the second region has a second conductivity type. The second conductivity type is different from the first conductivity type. The metal gate is disposed over the control gate. The dielectric structure is embedded in the metal gate and divides the metal gate into a first part and a second part. The dielectric structure is adjacent to the junction between the first region and the second region. The dielectric structure is in contact with the control gate. The source line and the drain line are disposed on opposite sides of the control gate.

### BACKGROUND OF THE INVENTION

### Field of the Invention

The present invention relates to semiconductor manufacturing, and, in particular, to testkey structures and methods for forming the same.

### Description of the Related Art

In order to improve the yield in semiconductor device production, a testkey structure is usually disposed to monitor whether defects are generated during the manufacturing process. This process can be adjusted to improve the level of performance of the semiconductor device. However, existing testkey structures and methods for forming the same still cannot meet the established requirements.

The process of manufacturing semiconductor devices is complex and ever-changing, and some manufacturing processes cannot be well monitored. Additionally, with the trend of miniaturization of electronic products, the size of testkey structures continues to decrease. Therefore, it is necessary to make further improvements to the testkey structure and the method for forming the same, so as to reduce the size of the testkey structure while accurately monitoring the manufacturing process of the semiconductor device.

### BRIEF SUMMARY OF THE INVENTION

According to some embodiments of the present disclosure, a testkey structure is provided. The testkey structure includes a substrate, a control gate, a metal gate, a dielectric structure, a source line, and a drain line. The control gate is disposed over the substrate and includes a first region and a second region. The first region is adjacent to the second region. The first region has a first conductivity type, and the second region has a second conductivity type. The second conductivity type is different from the first conductivity type. The metal gate is disposed over the control gate. The dielectric structure is embedded in the metal gate. The dielectric structure divides the metal gate into a first part and a second part. The dielectric structure is adjacent to a junction between the first region and the second region of the control gate. The dielectric structure is in contact with the control gate. The source line and the drain line are respectively disposed on opposite sides of the control gate.

According to some embodiments of the present disclosure, a testkey structure is provided. The testkey structure includes a substrate, a first memory cell, a second memory cell, and a conductive layer. The first memory cell is disposed over the substrate and includes a first control gate, a first metal gate, and a first dielectric structure. The first control gate has a first PN junction. The first metal gate is disposed over the first control gate. The first dielectric structure is disposed in the first metal gate, over the first PN junction of the first control gate and in contact with the first control gate. The second memory cell is disposed over the substrate and includes a second control gate, a second metal gate, and a second dielectric structure. The second control gate has a second PN junction. The second metal gate is disposed over the second control gate. The second dielectric structure is disposed in the second metal gate, over the second PN junction of the second control gate and in contact with the second control gate. The conductive layer electrically couples the first metal gate to the second metal gate.

According to some embodiments of the present disclosure, a method for forming a testkey structure is provided. The method includes forming a control gate over a substrate. The control gate has a first conductivity type. The method includes shielding a first region of the control gate and counter-doping the control gate, so that a second region of the control gate has a second conductivity type. The first region and the second region form a PN junction. The method includes forming a metal gate over the control gate. The method includes forming an opening that is over the PN junction of the control gate and passes through the metal gate. The opening exposes at least a portion of the second region of the control gate.

### BRIEF DESCRIPTION OF THE DRAWINGS

FIG. 1 is a top view illustrating a testkey structure according to some embodiments of the present disclosure.

FIG. 2 is a side view of the testkey structure in FIG. 1 from the first direction according to some embodiments of the present disclosure.

FIG. 3 is a cross-sectional view of the testkey structure in FIG. 1 along line I-I′ according to some embodiments of the present disclosure.

### DETAILED DESCRIPTION OF THE INVENTION

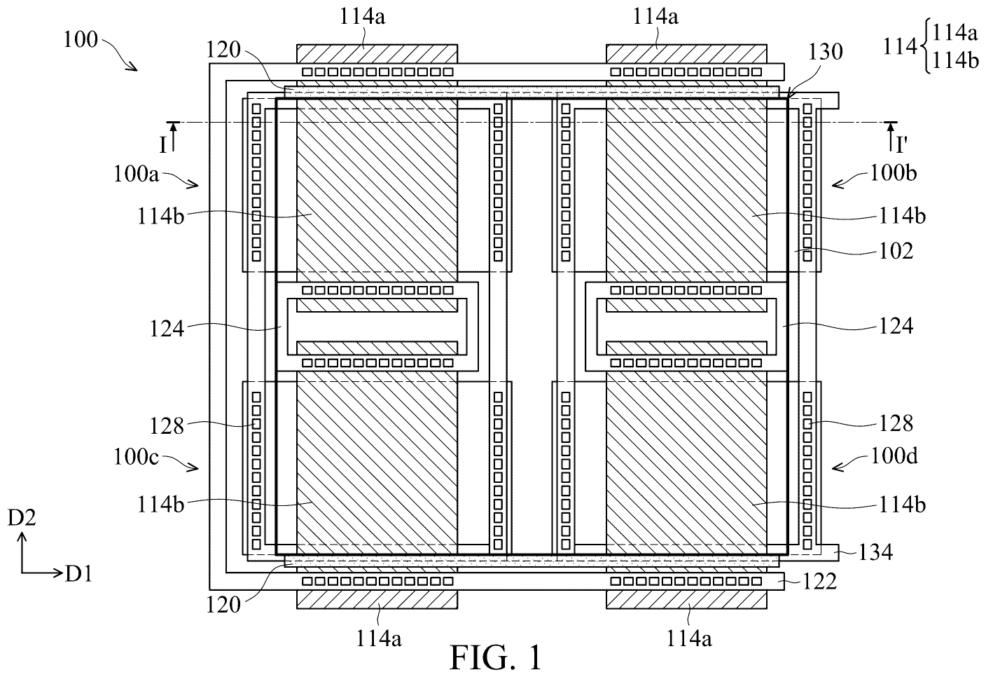

FIG. 1 is a top view illustrating a testkey structure 100 according to some embodiments. Additional components may be added to the testkey structure 100. Some of the components described below may be replaced or eliminated for different embodiments. To simplify the figures, only a part of the testkey structure 100 is shown. As shown in FIG. 1, the testkey structure 100 may include a plurality of memory cells disposed over the substrate 102, such as a first memory cell 100a, a second memory cell 100b, a third memory cell 100c, and a fourth memory cell 100d.

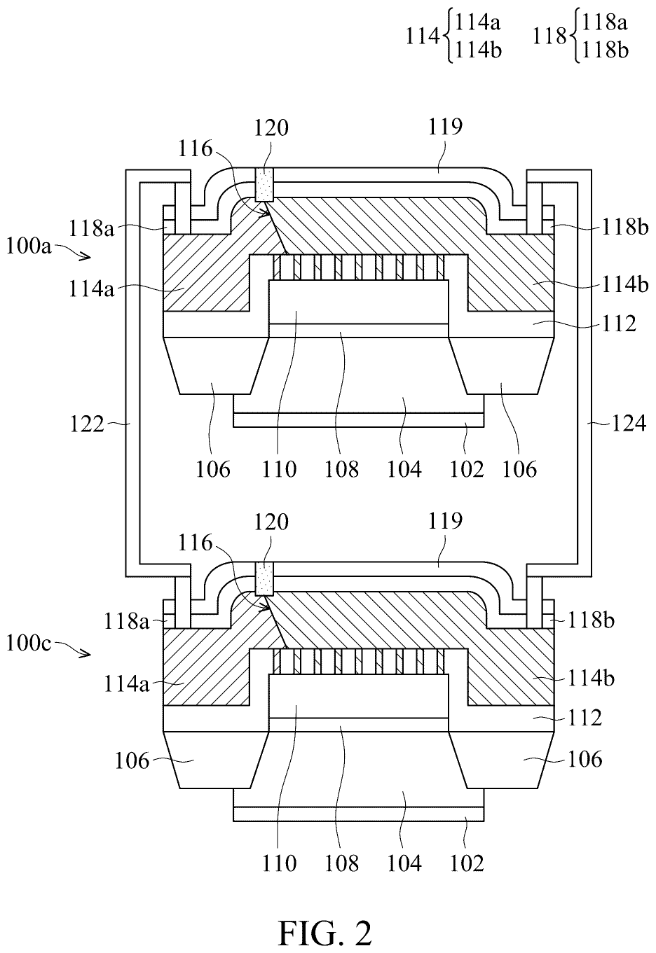

Viewed from the first direction D1, a side view of the testkey structure 100 in FIG. 1 is shown in FIG. 2, which illustrates the side view of the first memory cell 100a and the third memory cell 100c. In particular, FIG. 2 illustrates a cross-sectional view of the first memory cell 100a and the third memory cell 100c from the second direction D2, and the first memory cell 100a and the third memory cell 100c are disposed opposite to each other. The side view illustrating the second memory cell 100b and the fourth memory cell 100d may be similar to FIG. 2, and will not be repeated.

Referring to FIG. 2, the first memory cell 100a includes the substrate 102. The substrate 102 may use any substrate material suitable for memory cells, and may be a bulk semiconductor substrate or may include a composite substrate formed of different materials. One or more semiconductor elements (including active elements and/or passive elements) may be pre-formed on the substrate 102, and to simplify the figures, only the flat substrate 102 is shown herein.

According to some embodiments, as shown in FIG. 2, a well region 104 and an isolation structure 106 are formed in the substrate 102. The well region 104 may have a first conductivity type, such as P-type or N-type. The isolation structure 106 may be, for example, a shallow trench isolation structure, and may be used to isolate active regions from each other.

The isolation structure 106 may be formed by etching a trench in the substrate 102 using an etching process, and then filling the trench with the material of the isolation structure 106 by a deposition process. The material of the isolation structure 106 may include a dielectric material, such as silicon oxide, silicon nitride, silicon oxynitride, the like, or a combination thereof. According to some embodiments, the isolation structure 106 may include a multilayer structure, for example, having a dielectric liner.

According to some embodiments, as shown in FIG. 2, a gate dielectric layer 108 is formed over the well region 104. The gate dielectric layer 108 may be formed by a deposition process. The material of the gate dielectric layer 108 may include an oxide, such as silicon oxide, or any suitable material. According to some embodiments, the gate dielectric layer 108 may include a multilayer structure.

According to some embodiments, as shown in FIG. 2, a floating gate 110, an inter-gate dielectric layer 112, and a control gate 114 are sequentially formed over the gate dielectric layer 108. The control gate 114 allows charge to enter or leave the floating gate 110 for write or erase operations. In particular, during the write operation, charges may be made to enter the floating gate 110 from the substrate 102. Conversely, during the erase operation, charges may be removed from the floating gate 110.

The floating gate 110 may be formed by a deposition process. The material of the floating gate 110 may include any suitable material, such as polysilicon. The material of the floating gate 110 may be implanted with n-type or p-type dopants, and then an annealing process may be performed to activate the implanted dopants. Although a bulk floating gate 110 is shown, the floating gate 110 may include a first region having a first conductivity type and a second region having a second conductivity type. For example, the first region may be P-type and the second region may be N-type.

As shown in FIG. 2, the inter-gate dielectric layer 112 may be sandwiched between the floating gate 110 and the control gate 114 and may be in directly contact with the floating gate 110 and the control gate 114. The inter-gate dielectric layer 112 may be formed by a deposition process. In some embodiments, the material of the inter-gate dielectric layer 112 may include any suitable material, such as an oxide-nitride-oxide structure having a silicon nitride layer sandwiched between two silicon oxide layers. In other embodiments, the material of the inter-gate dielectric layer 112 may be a single layer, such as a single oxide layer or a single nitride layer.

The control gate 114 may be formed by a deposition process. The material of the control gate 114 may include any suitable material, such as polysilicon, and may be doped with n-type or p-type dopants. An annealing process may be performed to activate the implanted dopants.

According to some embodiments, the control gate 114 having the first conductivity type may be formed first. Then, a mask layer (not shown) may be formed over a first region 114a of the control gate 114 to shield the first region 114a of the control gate 114 and expose a second region 114b of the control gate 114. The mask layer may include a photoresist, a hard mask, or a combination thereof, and may be a single layer or a multilayer structure.

Next, a counter-doping process may be performed on the control gate 114 using different dopants, so that the exposed second region 114b has the second conductivity type. The first region 114a and the second region 114b of the control gate 114 may be disposed substantially over the first region and the second region of the floating gate 110, respectively. For example, the first region may be P-type and the second region may be N-type. Since the first conductivity type and the second conductivity type are different, a PN junction 116 may be formed between the first region 114a and the second region 114b of the control gate 114.

According to some embodiments, the substrate 102 has an array region and a peripheral region. Referring to FIG. 1, the range of the counter-doping process is shown as range 130, which substantially covers the peripheral region of the substrate 102. Therefore, the PN junction 116 of the control gate 114 is formed over the peripheral region.

Returning to FIG. 2, the inter-gate dielectric layer 112 may have a plurality of openings, and the control gate 114 may extend into these openings. Corresponding to the first region 114a and the second region 114b of the control gate 114, a portion of the control gate 114 in the inter-gate dielectric layer 112 may have a first conductivity type, and another portion of the control gate 114 may have a second conductivity type.

According to some embodiments, a bottom surface of the control gate 114 in the inter-gate dielectric layer 112 may be aligned with a bottom surface of the inter-gate dielectric layer 112, and the control gate 114 may be in contact with the floating gate 110. Alternatively, according to other embodiments, the bottom surface of the control gate 114 in the inter-gate dielectric layer 112 may extend below a top surface of the floating gate 110.

According to some embodiments, as shown in FIG. 2, a metal gate 118 is formed over the control gate 114. The metal gate 118 may be formed by a deposition process. The material of the metal gate 118 may include any suitable material, such as tungsten.

According to some embodiments, as shown in FIG. 2, a protective layer 119 is formed over the metal gate 118. The protective layer 119 may be formed by a deposition process. The material of the protective layer 119 may include any suitable material, such as silicon nitride.

Then, a dielectric structure 120 may be formed over the PN junction 116 of the control gate 114 and may pass through the metal gate 118 and the protective layer 119. The electrical properties of the PN junction 116 of the control gate 114 can be measured through the dielectric structure 120 to monitor the counter-doping process of the control gate 114. In particular, an interface between the region where the counter-doping process is performed and the region where the counter-doping process is not performed can be directly measured through the dielectric structure 120. Therefore, the counter-doping process can be performed only on the regions that need to have different conductivity types (e.g., peripheral regions), without the need to perform a wide range of counter-doping process for monitoring this process. As a result, the size of the testkey structure 100 can be reduced.

According to some embodiments, as shown in FIG. 2, the dielectric structure 120 is embedded in the metal gate 118 and the protective layer 119 and passes through the metal gate 118 and the protective layer 119. In particular, a bottom surface of the dielectric structure 120 may be leveled with a bottom surface of the metal gate 118. Alternatively, the bottom surface of the dielectric structure 120 may be lower than the bottom surface of the metal gate 118. Since the PN junction 116 is formed over the peripheral region, the dielectric structure 120 may be also formed over the peripheral region.

In the top view, as shown in FIG. 1, the dielectric structure 120 may extend continuously from one side of the metal gate 118 to the opposite side of the metal gate 118. As a result, as shown in FIG. 2, the metal gate 118 may be divided into a first part 118a and a second part 118b by the dielectric structure 120, but the present disclosure is not limited thereto.

The dielectric structure 120 may be formed by etching an opening (or a trench) in the metal gate 118 and the protective layer 119 by using an etching process, and then filling the opening (or the trench) by a deposition process with the material of electrical structure 120. The material of the dielectric structure 120 may include a dielectric material, such as silicon oxide, silicon nitride, silicon oxynitride, the like, or a combination thereof.

As shown in FIG. 2, the dielectric structure 120 may be in contact with the PN junction 116 of the control gate 114 and the first region 114a and the second region 114b of the control gate 114, but the present disclosure is not limited thereto. For example, due to possible process variations, such as the counter-doping process of the control gate 114 and/or the forming process of the dielectric structure 120 may be offset, the dielectric structure 120 may be adjacent to the PN junction 116 of the control gate 114 but may not be in contact with the PN junction 116 of the control gate 114. In these embodiments, the dielectric structure 120 may be in contact with the second region 114b of the control gate 114 but not the first region 114a of the control gate 114. The dielectric structure 120 may be disposed directly above a portion of PN junction 116.

According to some embodiments, as shown in FIG. 2, conductive layers 122 and 124 are formed over the protective layer 119 to electrically couple the first memory cell 100a to the third memory cell 100c. The conductive layer 122 may electrically couple the first part 118a of the metal gate 118 of the first memory cell 100a to the first part 118a of the metal gate 118 of the third memory cell 100c, and the conductive layer 124 may electrically couple the second part 118b of the metal gate 118 of the first memory cell 100a to the second part 118b of the metal gate 118 of the third memory cell 100c.

The conductive layers 122 and 124 may be formed by a deposition process. The materials of conductive layers 122 and 124 may include metals, such as copper, aluminum, the like, or a combination thereof.

Referring back to FIG. 1, the testkey structure 100 may include the first memory cell 100a, the second memory cell 100b, the third memory cell 100c, and the fourth memory cell 100d. The components of the second memory cell 100b, the third memory cell 100c, and the fourth memory cell 100d may be similar to those of the first memory cell 100a, and will not be repeated. The testkey structure 100 may include more or less memory cells than illustrated.

As shown in FIG. 1, the conductive layer 122 may electrically couple the first memory cell 100a to the second memory cell 100b and electrically couple the third memory cell 100c to the fourth memory cell 110d in the first direction D1, and may electrically couple the first memory cell 100a to the third memory cell 100c in the second direction D2. The first direction D1 is different from the second direction D2. The first direction D1 may be substantially perpendicular to the second direction D2. According to some embodiments, the angle between the first direction D1 and the second direction D2 is about 85° to 90°.

As shown in FIG. 1, the conductive layer 124 may electrically couple the first memory cell 100a to the third memory cell 100c, and may electrically couple the second memory cell 100b to the fourth memory cell 100d. The testkey structure 100 may also have additional conductive layer(s) (not shown) for electrically coupling the two conductive layers 124, so that the first memory cell 100a and the third memory cell 100c may be electrically coupled to the second memory cell 100b and the fourth memory cell 100d.

As shown in FIG. 1, the dielectric structure 120 may extend in the first direction D1 and may be adjacent to the range 130 of the counter-doping process and the conductive layer 122 in the first direction D1. According to some embodiments, the dielectric structure 120 of the first memory cell 100a may be connected to the dielectric structure 120 of the second memory cell 100b, and the dielectric structure 120 of the third memory cell 100c may be connected to the dielectric structure 120 of the fourth memory cell 100d.

As shown in FIG. 1, the testkey structure 100 may include source/drain lines 128. The source/drain lines 128 may electrically couple the first memory cell 100a to the third memory cell 100c and electrically couple the second memory cell 100b to the fourth memory cell 100d in the second direction D2, and may electrically couple the first memory cell 100a to the second memory cell 100b and electrically couple the third memory cell 100c to the fourth memory cell 100d in the first direction D1.

As shown in FIG. 1, the range 130 of the counter-doping process may cover the second region 114b of the control gate 114 and one of the source/drain lines 128 of the first memory cell 100a and the third memory cell 100c (e.g., a source line), and may expose the other (e.g., a drain line) of the source/drain lines 128 of the first memory cell 100a and the third memory cell 100c. Similarly, the range 130 of the counter-doping process may cover one of the source/drain lines 128 (e.g., drain lines) of the second memory cell 100b and the fourth memory cell 100d, and may expose the other (e.g., the source line) of the source/drain lines 128 of the second memory cell 100b and the fourth memory cell 100d. Compared with the testkey structure that requires the counter-doping process to cover the entire memory cell (100a, 100b, 100c, 100d) (including both of the source line and the drain line), the testkey structure 100 according to the embodiments of the present disclosure can reduce the scope 130 of the counter-doping process, thereby reducing the size of the device.

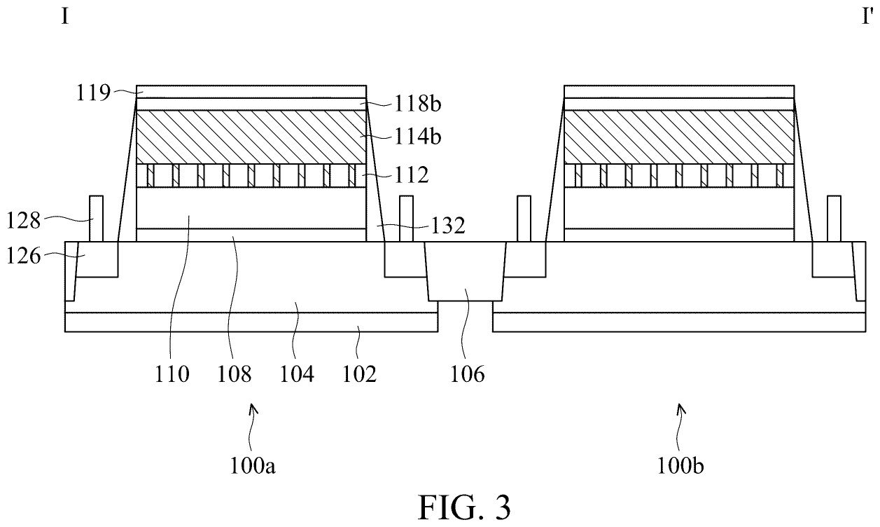

The testkey structure 100 illustrated along the line I-I′ (substantially parallel to the first direction D1) may be shown in FIG. 3. In particular, FIG. 3 illustrates a cross-sectional view of the first memory cell 100a and the second memory cell 100b along the line I-I′. The third memory cell 100c and the fourth memory cell 100d may have similar cross-sectional views, and will not be repeated.

In FIG. 1, the range 130 of the counter-doping process may be beyond the sidewalls of the control gate 114 in the first direction D1. Therefore, only the second region 114b of the control gate 114 is shown in FIG. 3. However, the present disclosure is not limited thereto. In some embodiments, the range 130 of the counter-doping process may also be located within one or more sidewalls of the control gate 114 in the first direction D1, such that the first region 114a, the second region 114b, and the junction 116 of the control gate 114 may appear in the first memory cell 100a and/or the second memory cell 100b in FIG. 3.

According to some embodiments, as shown in FIG. 3, source/drain regions 126 are disposed in the well region 104. The well region 104 may have a first conductivity type and the source/drain regions 126 may have a second conductivity type different from the first conductivity type. The source/drain regions 126 may be formed by doping the substrate 102.

Then, source/drain lines 128 (including source/drain contacts) may be formed over the source/drain regions 126, respectively. The source/drain lines 128 may be formed by a deposition process. The material of the source/drain lines 128 may include metals, such as copper, aluminum, the like, or a combination thereof.

According to some embodiments, as shown in FIG. 3, the first memory cell 100a includes a dielectric layer 132 disposed over the substrate 102. The dielectric layer 132 may cover both sidewalls of the gate dielectric layer 108, the floating gate 110, the inter-gate dielectric layer 112, the control gate 114 and the metal gate 118. The dielectric layer 132 may be formed by a deposition process. The material of the dielectric layer 132 may include a dielectric material, such as silicon oxide, silicon nitride, silicon oxynitride, the like, or a combination thereof.

In summary, the testkey structure provided by the embodiments of the present disclosure can monitor the counter-doping process by disposing a dielectric structure on the boundary of the counter-doping process, while reducing the range required for the counter-doping process, thereby reducing the size of the testkey structure.

The foregoing outlines features of several embodiments so that those skilled in the art may appreciate that they may readily use the present disclosure as a basis for designing or modifying other processes and structures for carrying out the same purposes and/or achieving the same advantages of the embodiments introduced herein. Various changes, substitutions, and alterations may be made to such equivalent constructions without departing from the spirit and scope of the present disclosure.

What is claimed is:

1. A testkey structure, comprising:
a control gate disposed over a substrate and comprising a first region and a second region which are adjacent to each other, wherein the first region has a first conductivity type, and the second region has a second conductivity type which is different from the first conductivity type;
a metal gate disposed over the control gate;
a dielectric structure embedded in the metal gate and dividing the metal gate into a first part and a second part, wherein the dielectric structure is adjacent to a junction between the first region and the second region of the control gate and is in contact with the control gate; and
a source line and a drain line respectively disposed on opposite sides of the control gate.

2. The testkey structure as claimed in claim 1, wherein the dielectric structure is in contact with the junction and the first region of the control gate.

3. The testkey structure as claimed in claim 1, wherein the dielectric structure extends in a first direction, and the source line and the drain line extend in a second direction that is different from the first direction.

4. The testkey structure as claimed in claim 1, wherein the first conductivity type is P-type, and the second conductivity type is N-type.

5. The testkey structure as claimed in claim 1, wherein the first part of the metal gate partially covers the first region of the control gate, and the second part of the metal gate partially covers the second region of the control gate.

6. The testkey structure as claimed in claim 1, wherein the dielectric structure extends into the control gate.

7. The testkey structure as claimed in claim 1, wherein the material of the metal gate includes tungsten.

8. A testkey structure, comprising:
a first memory cell disposed over a substrate and comprising:
a first control gate having a first PN junction;
a first metal gate disposed over the first control gate; and
a first dielectric structure disposed in the first metal gate, over the first PN junction of the first control gate and in contact with the first control gate;
a second memory cell disposed over the substrate and comprising:
a second control gate having a second PN junction;
a second metal gate disposed over the second control gate; and
a second dielectric structure disposed in the second metal gate, over the second PN junction of the second control gate and in contact with the second control gate; and
a conductive layer electrically coupling the first metal gate to the second metal gate.

9. The testkey structure as claimed in claim 8, wherein the substrate has an array region and a peripheral region, and the first dielectric structure and the second dielectric structure are over the peripheral region.

10. The testkey structure as claimed in claim 8, wherein the first dielectric structure and the second dielectric structure are adjacent to the conductive layer.

11. The testkey structure as claimed in claim 8, wherein the conductive layer extends in the first direction, and the first dielectric structure and the second dielectric structure extend substantially in the first direction.

12. The testkey structure as claimed in claim 11, wherein the first memory cell further comprises a source line and a drain line respectively disposed on opposite sides of the first control gate and extending in a second direction that is different from the first direction.

13. The testkey structure as claimed in claim 12, further comprising a third memory cell, wherein the conductive layer electrically couples the first memory cell to the third memory cell.

14. The testkey structure as claimed in claim 8, wherein the first dielectric structure is in contact with the first PN junction.

15. The testkey structure as claimed in claim 8, wherein the first dielectric structure is connected to the second dielectric structure.

16. A method for forming a testkey structure, comprising:
forming a control gate over a substrate, wherein the control gate has a first conductivity type;
shielding a first region of the control gate and counter-doping the control gate, so that a second region of the control gate has a second conductivity type, and the first region and the second region form a PN junction;
forming a metal gate over the control gate; and
forming an opening over the PN junction of the control gate and passing through the metal gate, wherein the opening exposes at least a portion of the second region of the control gate.

17. The method as claimed in claim 16, wherein the opening exposes the PN junction of the control gate.

18. The method as claimed in claim 16, wherein the opening extends from a first side to a second side of the metal gate and divides the metal gate into a plurality of parts.

19. The method as claimed in claim 16, further comprising forming a source line and a drain line on opposite sides of the control gate, wherein the counter-doping is not performed directly above the source line and/or the drain line.

20. The method as claimed in claim 16, further comprising forming a dielectric structure in the opening.
